(19) United States
(12) Patent Application Publication
(10) Pub. No.: US 2009/0236701 A1
(43) Pub. Date: Sep. 24, 2009

(54) Chip arrangement and a method of determining an inductivity compensation structure for compensating a bond wire inductivity in a chip arrangement

(75) Inventors: Mei Sun, Singapore (SG); Yue Ping Zhang, Singapore (SG)

Correspondence Address: DAVIDSON BERQUIST JACKSON & GOWDEY LLP, 4300 WILSON BLVD., 7TH FLOOR, ARLINGTON, VA, 22203, US

(73) Assignee: Nanyang Technological University, Singapore (SG)

(21) Appl. No.: 12/076,380

(22) Filed: Mar. 18, 2008

(51) Int. Cl. H01L 23/58; H01L 23/49; G06F 17/50

(52) U.S. Cl. 257/665; 703/14; 257/E23.024

(57) ABSTRACT

A chip arrangement is disclosed. The chip arrangement includes a first chip, a first bond wire having an inductive element and coupled with the first chip at its one end and an inductivity compensation structure including a first conductive plate coupled with the first bond wire at the other end of the first bond wire, and a second conductive plate arranged in parallel to the first conductive plate, wherein the first conductive plate and the second conductive plate are configured such that a resonant condition for a partial circuit formed by the first bond wire and the inductivity compensation structure is formed to compensate for the inductive element of the first bond wire. A method of determining an inductivity compensation structure for compensating a bond wire inductivity in a chip arrangement is also disclosed.

### FIELD OF THE INVENTION

Embodiments of the invention relate generally to a chip arrangement and a method of determining an inductivity compensation structure for compensating a bond wire inductivity in a chip arrangement.

### BACKGROUND OF THE INVENTION

Bond wires have been widely used in the fabrication of monolithic and hybrid integrated circuits because of the rather simple and reliable process involved. Typical bond wire connections include a chip-to-chip interconnect or a chip-to-substrate interconnect. In a chip-to-chip interconnect, one end of the bond wire may be attached to a chip or die and the other end of the bond wire may be attached to another chip or die to realize the chip-to-chip interconnect. In a chip-to-substrate interconnect, one end of the bond wire may be attached to a chip or die and the other end of the bond wire may be attached to a substrate contact to realize the chip-to-substrate interconnect. With this bond wire connection style, the typical parasitics that are usually tolerated at lower frequencies cannot be ignored at millimeter wave (mmWave) frequencies.

One of the typical parasitics is the relatively significant series inductance of the bond wire at mmWave frequencies, which may greatly limit the external performance of mmWave devices. To try to compensate for the high inductance of the bond wire at mmWave frequencies, efforts have usually focused on reducing the length of the bond wire and also reducing the chip-to-chip or chip-to-substrate spacing. However, this approach may soon meet the limitations in manufacturing, which require the longer bond wire lengths to improve manufacturability and wider chip-to-chip or chip-to-substrate spacing to improve the yields of mmWave multichip assemblies.

An alternative approach involves the use of discrete components to tune the inductance of the bond wire to a resonant condition. However, discrete components can be bulky and may not be compatible with the miniaturization requirement at mmWave frequencies. Their inherent parasitics can also make the accurate tuning at mmWave frequencies impractical.

Another approach involve the use of a ribbon instead of a bond wire for interconnect at mmWave frequencies. However, for the reliable fabrication, it is not as effective as the bond wire.

A further approach involves a basic five-stage low-pass filter theory which has been used to compensate the bond wire high inductance. However, the compensation method may be complex and this approach requires an optimization of the dimensions of the bond pads and their gaps in order for the whole bond wire interconnect to achieve good performance. Another similar compensation technique involves the use of a T-network.

Yet another approach involves the use of a simple meander line structure for bond wire compensation. However, the combined length of the bond wire and matching element is a half of a guided wavelength at the operating frequency. This might take up too much area for the typical bond wire contacts.

Therefore, there is still a need for a reliable, compact, cost-effective bond wire inductivity compensation structure at mmWave frequencies.

### SUMMARY OF THE INVENTION

In various embodiments of the invention, a chip arrangement is provided, which is reliable, compact, easy and cost-effective to fabricate. A method of determining an inductivity compensation structure for compensating a bond wire inductivity in a chip arrangement is also provided.

An embodiment of the invention relates to a chip arrangement. The chip arrangement includes a first chip, a first bond wire having an inductive element and coupled with the first chip at its one end, an inductivity compensation structure comprising a first conductive plate coupled with the first bond wire at the other end of the first bond wire, and a second conductive plate arranged substantially in parallel to the first conductive plate wherein the first conductive plate and the second conductive plate are configured such that a resonant condition for a partial circuit formed by the first bond wire and the inductivity compensation structure is formed to compensate for the inductive element of the first bond wire.

In an embodiment, the second conductive plate may form part of an antenna. Further, the first conductive plate and the second conductive plate may be arranged on different chip arrangement manufacturing planes. In this regard, the inductivity compensation structure is arranged in series with the first bond wire.

In an embodiment, the first conductive plate may form part of the antenna. The first conductive plate may have a T-shape and the second conductive plate may substantially surround the first conductive plate. Further, the first conductive plate and the second conductive plate may be arranged on a single chip arrangement manufacturing plane. In this regard, the inductivity compensation structure may be arranged substantially in parallel or in shunt configuration with the first bond wire.

In an embodiment, the chip arrangement may further include a second chip, wherein the second conductive plate forms part of the second chip. The chip arrangement may further include a plurality of other chips. The first chip and the second chip may include an integrated circuit.

In an embodiment, the first conductive plate and the second conductive plate may include a metallic material. The metallic material may include copper, silver and gold but not so limited.

In an embodiment, the first chip includes a signal pad and the first bond wire is coupled with the signal pad on the first chip at its one end.

In an embodiment, the first chip further includes a first ground pad and the signal pad is coupled to the first ground pad via a capacitivity compensation structure. The capacitivity compensation structure may be of an inductive nature to compensate for the capacitance formed between the signal pad and a chip ground.

In an embodiment, the chip arrangement includes a second bond wire having an inductive element and coupled with the first chip at its one end. The second bond wire may be coupled with the first ground pad on the first chip at its one end.

In an embodiment, the first chip includes a second ground pad.

In an embodiment, the chip arrangement includes a third bond wire having an inductive clement and coupled with the first chip at its one end. The third bond wire may be coupled with the second ground pad on the first chip at its one end.

Another embodiment of the invention relates to a method of determining an inductivity compensation structure for compensating a bond wire inductivity in a chip arrangement. The method includes determining the inductivity of the bond wire and determining a first conductive plate coupled with the bond wire at its one end, and a second conductive plate arranged substantially in parallel to the first conductive plate, which form the inductivity compensation structure such that a resonant condition for a partial circuit formed by the bond wire and the inductivity compensation structure is formed to compensate for the inductivity of the bond wire.

In an embodiment, determining the inductivity of the bond wire includes identifying the bond wire to be compensated.

In an embodiment, determining the inductivity of the bond wire further includes identifying an operation frequency and an operation bandwidth. The operation frequency may be in the mmWave range. The operation bandwidth may depend on the type of applications. As an example, for the 60 GHz wireless personal network application, it may be an operation frequency of about 60 GHz with a bandwidth of about 7 GHz.

In an embodiment, determining the inductivity of the bond wire further includes modeling the bond wire to be compensated.

In an embodiment, determining the inductivity of the bond wire further includes simulating an electrical performance of the modeled bond wire at the operation frequency.

In an embodiment, the second conductive plate may form part of an antenna. The first conductive plate and the second conductive plate may be arranged on different chip arrangement manufacturing planes. The inductivity compensation structure may be arranged in series with the bond wire.

In an embodiment, the first conductive plate may form part of the antenna. The first conductive plate may have a T-shape and the second conductive plate may substantially surround the first conductive plate. The first conductive plate and the second conductive plate may be arranged on a single chip arrangement manufacturing plane. The inductivity compensation structure may be arranged substantially in parallel or in shunt configuration with the bond wire.

In an embodiment, the first conductive plate may form part of a first chip and the second conductive plate may form part of a second chip. The first chip and the second chip may include an integrated circuit.

In an embodiment, the first conductive plate and the second conductive plate may include a metallic material. The metallic material may include copper, silver and gold but not so limited.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a chip arrangement including an inductivity compensation structure according to an embodiment of the present invention;

FIG. 2 shows a chip arrangement including two inductivity compensation structures according to another embodiment of the present invention;

FIG. 3 shows a chip arrangement without an inductivity compensation structure according to an embodiment of the present invention;

FIG. 4 shows a chip arrangement including an inductivity compensation structure according to a further embodiment of the present invention;

FIG. 5 shows a plot of reactance versus frequency according to an embodiment of the present invention;

FIG. 6 shows a plot of return loss versus frequency according to an embodiment of the present invention;

FIG. 7 shows a chip arrangement including a capacitivity compensation structure according to an embodiment of the present invention;

FIG. 8 shows a chip arrangement including a capacitivity compensation structure according to another embodiment of the present invention;

FIG. 9 shows a chip arrangement including a capacitivity compensation structure according to another further embodiment of the present invention;

FIG. 10 shows a chip arrangement including an inductivity compensation structure according to a further embodiment of the present invention;

FIG. 11 shows a method of determining an inductivity compensation structure for compensating a bond wire inductivity in a chip arrangement according to an embodiment of the present invention;

FIG. 12 shows a method of implementing an inductivity compensation structure for compensating a bond wire inductivity in a chip arrangement according to an embodiment of the present invention;

### DETAILED DESCRIPTION OF THE INVENTION

Exemplary embodiments of a chip arrangement and a method of determining an inductivity compensation structure for compensating a bond wire inductivity in a chip arrangement, are described in details below with reference to the accompanying figures. In addition, the exemplary embodiments described below can be modified in various aspects without changing the essence of the invention.

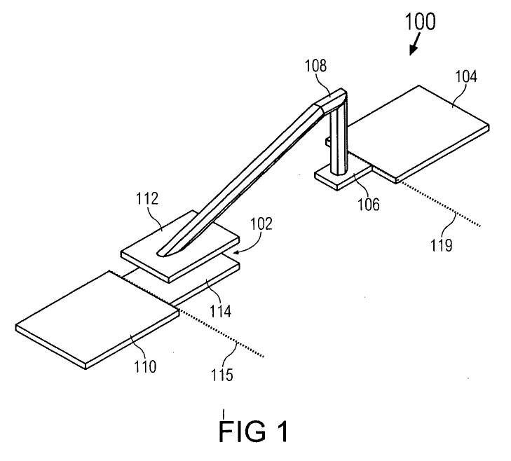

FIG. 1 shows a chip arrangement 100 including an inductivity compensation structure 102 according to an embodiment of the present invention. The chip arrangement 100 includes a chip 104, a chip connector 106 or a chip pad, a bond wire 108, an inductivity compensation structure 102 and a feedline 110 of an antenna. The chip 104 may include an integrated circuit. The chip connector 106 or chip pad may be positioned adjacent to the chip 104 or positioned on the chip 104 and configured for external connection. The bond wire 108 includes an inductive element and is coupled with the chip pad 106 at its one end and with the inductivity compensation structure 102 at the other end. The inductivity compensation structure 102 includes a first conductive plate 112 and a second conductive plate 114 arranged substantially in parallel to the first conductive plate 112. The first conductive plate 112 is coupled with the bond wire 108 at the end of the bond wire 108 opposite the chip connector 106. The first 112 and the second 114 conductive plates are configured such that a resonant condition for a partial circuit formed by the bond wire 108 and the inductivity compensation structure 102 is formed to compensate for the inductive element of the bond wire 108. The second conductive plate 114 may form part of the antenna or is connected to the feedline 110 of the antenna. FIG. 1 shows two virtual planes 115, 119 which may be used to distinguish the combination of the inductivity compensation structure 102, the bond wire 108 and the chip connector 106 from the respective feedline 100 of the antenna or the chip 104. The virtual plane 115 tries to provide a distinction between the combination of the inductivity compensation structure 102, the bond wire 108 and the chip connector 106 from the respective feedline 100 of the antenna. The second conductive plate 114 of the inductivity compensation structure 102 may be in the same plane as the feedline 100 of the antenna. The second conductive plate 114 of the inductivity compensation structure 102 may also be in the same virtual plane 115 as any other structures to be compensated besides the feedline 100 of the antenna. The virtual plane 119 tries to provide a distinction between the combination of the inductivity compensation structure 102, the bond wire 108 and chip connector 106 from the chip 104. The chip connector 106 may be in the same plane as the chip 104.

In FIG. 1, the inductivity compensation structure 102 may be a serial capacitor element used to tune the inductance of the bond wire 108 to a resonant condition, thus compensating the bond wire 108 high inductance at a resonant frequency. In the mmWave range, the form factor of the capacitor element for compensation may be on the order of several hundred micros or less, thereby making the inductivity compensation structure 102 relatively compact. In addition, the inductivity compensation structure 102 is reliable and cost-effective to manufacture. The inductivity compensation structure 102 may be used for chip-to-chip and chip-to-substrate connections at mmWave frequencies. This will be desirable for highly integrated mmWave wireless devices which has a requirement for miniaturization, manufacturing reliability and mass production cost-effectiveness.

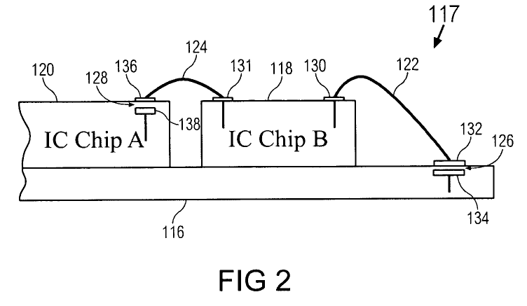

FIG. 2 shows a chip arrangement 117 including two inductivity compensation structures 126, 128 according to another embodiment of the present invention. The chip arrangement 117 includes a substrate 116, a first chip 118, a second chip 120, a first bond wire 122, a second bond wire 124, a first inductivity compensation structure 126 and a second inductivity compensation structure 128. The substrate 116 may be any suitable substrate, for example a package substrate such as low temperature co-fired ceramic (LTCC), Flame Retardant 4 (FR4) substrate, liquid crystal polymer (LCP) substrate, Teflon (PTFE) substrate but not so limited. The first chip 118 and the second chip 120 may include an integrated circuit. The first bond wire 122 includes an inductive element and couples the first chip 118 to the package substrate 116. In particular, one end of the first bond wire 122 is coupled to a first chip connector 130 or first chip pad positioned on the first chip 118 and the other end of the first bond wire 122 is coupled to the first inductivity compensation structure 126 formed on the package substrate 116. The first inductivity compensation structure 126 includes a first conductive plate 132 and a second conductive plate 134. The first conductive plate 132 may be coupled to one end of the first bond wire 122. As shown in FIG. 2, the first conductive plate may be positioned on the package substrate 116 or a portion of the first conductive plate may be embedded in the package substrate 116 and the second conductive plate 134 may be embedded in the package substrate 116. The first conductive plate 132 is arranged substantially in parallel and at a distance away from the second conductive plate 134. The first 132 and the second 134 conductive plates are configured such that a resonant condition for a partial circuit formed by the first bond wire 122 and the first inductivity compensation structure 126 is formed to compensate for the inductive element of the first bond wire 122.

The second bond wire 124 also includes an inductive element and couples the first chip 118 to the second chip 120. In particular, one end of the second bond wire 124 is coupled to a second chip connector 131 or second chip pad positioned on the first chip 118 and the other end of the second bond wire 124 is coupled to a second inductivity compensation structure 128 formed on the second chip 120. The second inductivity compensation structure 128 includes a first conductive plate 136 and a second conductive plate 138. The first conductive plate 136 may be coupled to one end of the second bond wire 124. As shown in FIG. 2, the first conductive plate 136 may be positioned on the second chip 120 or a portion of the first conductive plate 136 may be embedded in the second chip 120 and the second conductive plate 138 may be embedded in the second chip 120. The first conductive plate 136 is arranged substantially in parallel and at a distance away from the second conductive plate 138. The first 136 and the second 138 conductive plates are configured such that a resonant condition for a partial circuit formed by the second bond wire 124 and the second inductivity compensation structure 128 is formed to compensate for the inductive element of the second bond wire 124.

The respective first 126 and the second 128 inductivity compensation structures may include a respective capacitor element used to tune the inductance of the respective first 122 and second 124 bond wires to a resonant condition, thus compensating the high inductance of the respective bond wires 122, 124 at a resonant frequency.

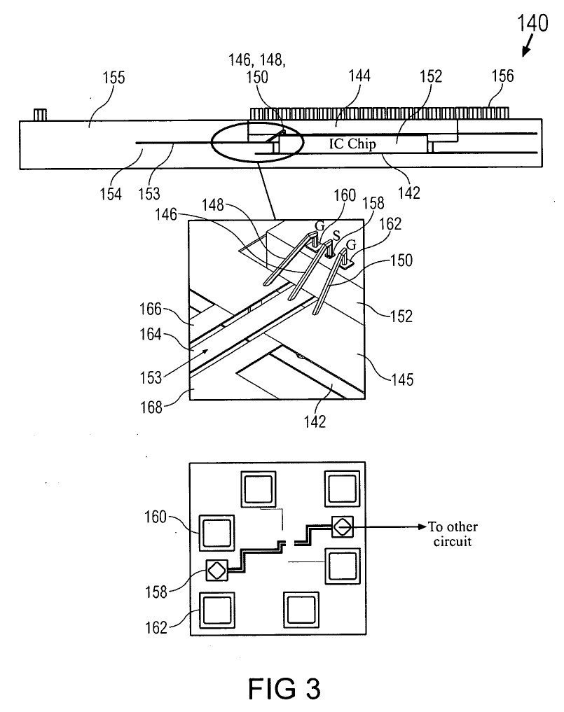

FIG. 3 shows a chip arrangement 140 without an inductivity compensation structure according to an embodiment of the present invention. In FIG. 3, the chip arrangement 140 includes a chip 152, a chip ground 142, a cavity 144 for housing the chip 152, a plurality of bond wires 146, 148, 150, an antenna 153 housed in a package 155 (or an antenna-in-package (AIP) 154), a first ground conductive plate 143, a second ground conductive plate 145 and solder balls 156 in the package 155 for connection from the chip 152 to the outside package. The chip 152 may be an integrated circuit that includes a radio frequency integrated circuit (RFIC) with each output via the respective chip pads on the chip 152, namely a first ground (G) pad 160, a signal (S) pad 158 and a second ground (G) pad 162. Beside RFIC part the chip 152 may include other functional circuits, such as low frequency integrated circuits. These respective pads 158, 160, 162 may be positioned adjacent to each other in the respective order of a first ground pad 160, a signal pad 158 and a second ground pad 162 on a surface of a chip 152. The chip 152 may be connected to or positioned on the chip ground 142. The antenna-in-package 154 includes a plurality of feedlines, namely a first ground feedline 166, a signal feedline 164 and a second ground feedline 168. The first conductive plate 143 is in connection with the first ground feedline 166 and the second conductive plate 145 is in connection with the second ground feedline 168. The first conductive plate 143 is connected to the first ground pad 160 via the bond wire 148. The second conductive plate 145 is connected to the second ground pad 162 via the bond wire 150 The signal feedline 164 is connected to signal pad 158 via the bond wire 146. The first conductive plate 143 and the second conductive plate 145 may also be connected to the chip ground 142 via a via or a plurality of vias. The first conductive plate 143 and the second conductive plate 145 may also be a single conductive plate.

In particular, FIG. 3 shows a configuration of a highly integrated mmWave antenna 153 in a ball grid array package 155. The whole package 155 forms a single-package radio with a chip 152 loaded into a package cavity 144. For the signals from a chip 152, the low frequency ones will be connected to the signal traces and then to solder balls 156 in the package 155 and then finally to the outside mother board. The radio frequency ones will be connected to the antenna-in-package (AIP) 154 to radiate to the air.

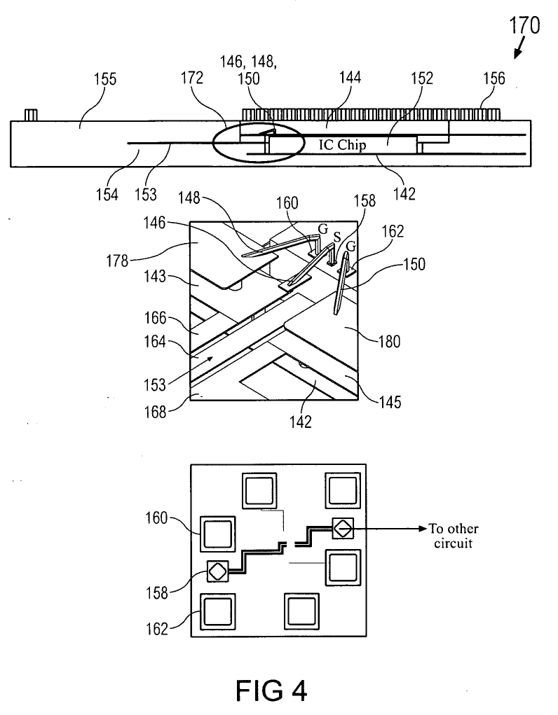

FIG. 4 shows a chip arrangement 170 including an inductivity compensation structure 172 according to a further embodiment of the present invention. FIG. 4 is essentially the same as FIG. 3 with an additional signal conductive plate 174 and two additional ground conductive plates 178, 180. In FIG. 4, the chip arrangement 170 includes a chip 152, a chip ground 142, a cavity 144 for housing the chip 152, a plurality of bond wires 146, 148, 150, an antenna 153 housed in a package 155 (or to an antenna-in-package 154), a first ground conductive plate 143, a second ground conductive plate 145, a third ground conductive plate 178, a fourth ground conductive plate 180, a signal conductive plate 174, and solder balls 156 in the package 155 for connection from the chip 152 to the outside package.

Like in FIG. 3, the chip 152 includes a plurality of chip pads, namely a first ground (G) pad 160, a signal (S) pad 158 and a second ground (G) pad 162. These respective pads 158, 160, 162 may be positioned adjacent to each other in the respective order of a first ground pad 160, a signal pad 158 and a second ground pad 162 on a surface of a chip 152. The chip 152 may be connected to or positioned on the chip ground 142. The antenna-in-package 154 includes a plurality of feedlines, namely a first ground feedline 166, a signal feedline 164 and a second ground feedline 168. The first conductive plate 143 is in connection with the first ground feedline 166 and the second conductive plate 145 is in connection with the second ground feedline 168. The third conductive plate 178 is arranged in parallel and at a distance away from the first conductive plate 143. The fourth conductive plate 180 is arranged in parallel and at a distance away from the second conductive plate 145. The first conductive plate 143 may be connected to the chip ground 142 via a via or a plurality of vias and the third conductive plate 178 may be connected to the first conductive plate 143 via a via or a plurality of vias. Similarly, the second conductive plate 145 may be connected to the chip ground 142 via a via or a plurality of vias and the fourth conductive plate 180 may be connected to the second conductive plate 145 via a via or a plurality of vias. The third conductive plate 178 is connected to the first ground pad 160 via the bond wire 148. The fourth conductive plate 180 is connected to the second ground pad 162 via the bond wire 150.

The signal conductive plate 174 is arranged in parallel and at a distance away from the signal feedline 164. The signal conductive plate 174 and the signal feedline 164 form the inductivity compensation structure 172. The signal conductive plate 174 is connected to the signal pad 158 via the bond wire 146. The inductivity compensation structure 172 corresponds to the signal path from the chip 152 to the antenna-in-package 154 The signal conductive plate 174 and the signal feedline 164 are configured such that a resonant condition for a partial circuit formed by the bond wire 146 and the inductivity compensation structure 172 is formed to compensate for the inductive element of the bond wire 146 connecting from the signal pad 158 to the signal conductive plate 174.

The first conductive plate 143 and the second conductive plate 145 may be a single conductive plate. The third conductivity plate 178 and the fourth conductive plate 180 may be a single conductive plate.

The first 143, second 145, third 178 and fourth 180 ground conductive plates, bond wires 148, 150 connecting the third 178 and fourth 180 ground conductive plates to the first 160 and second ground pads 162, and the first 160 and second 162 ground pads in the ground paths are all connected together to form a ground environment for the signal path.

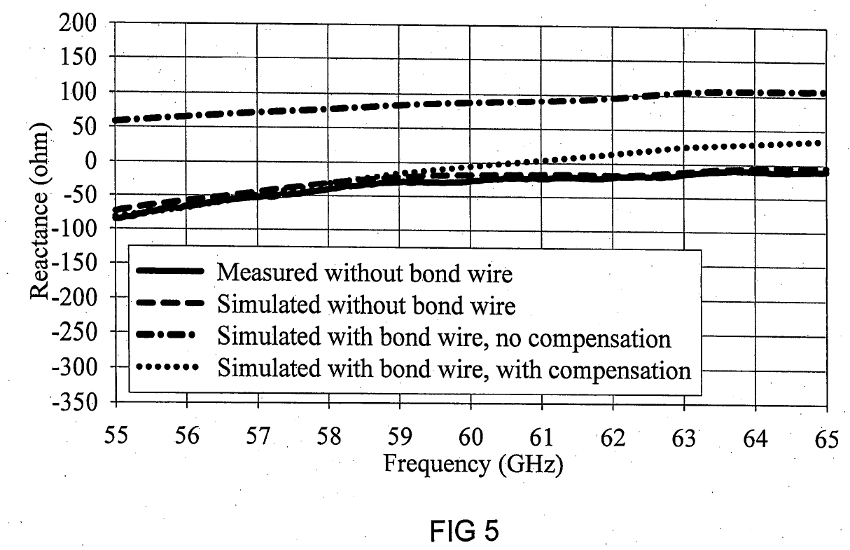

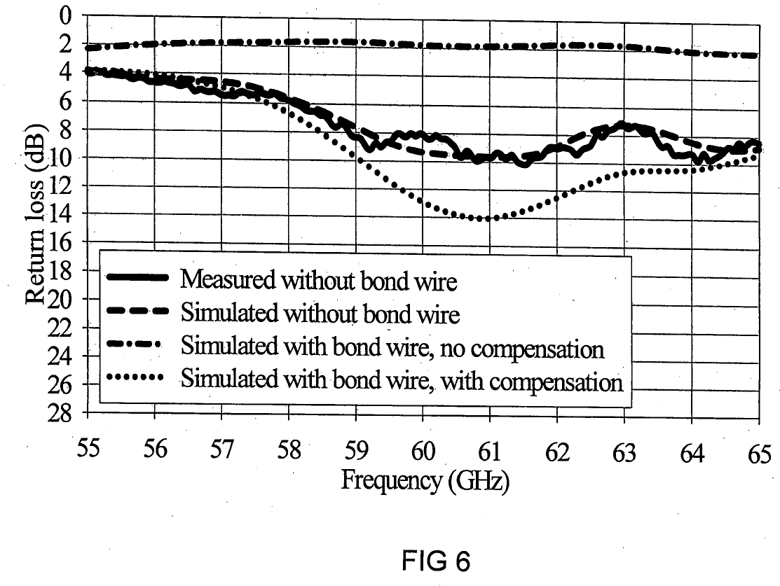

Owing to the mmWave radio frequency operation, the connection between the chip or die and the antenna is of great importance. A big challenge is that the traditional bond wire shows a relatively high inductance if there is no compensation. FIG. 5 shows a plot 186 of reactance versus frequency according to an embodiment of the present invention and FIG. 6 shows a plot 188 of return loss versus frequency according to an embodiment of the present invention.

As shown in FIG. 5, the connection of an approximately 400 μm in length 25.4 μm in diameter bond wire will introduce an approximate 120 ohm reactance at the interested frequency band of between about 55 GHz to about 65 GHz. Accordingly, the antenna's return loss degrades greatly as seen in FIG. 6. It is shown that there is a 7.9 dB decrease in return loss from 9.8 dB to 1.9 dB at about 61 GHz. From FIGS. 5 and 6, it may be seen that the antenna may not work well with the bond wire connected.

By constructing a compensation capacitor in serial with the bond wire for the central RF signal as shown in FIG. 4, the reactance at the frequency band of between about 55 to about 65 GHz has been compensated successfully as shown in FIG. 5. It is also found from FIG. 6 that the antenna's return loss is now better than the measured and simulated return loss value without bond wire, which is about 10 dB from a frequency band of between about 59 GHz to about 64 GHz, thereby indicating an acceptable matching to a 50-ohm source.

The other parameters of the antenna performance, such as gain, efficiency and patterns, are also acceptable after compensation. The results in FIGS. 5 and 6 shows that the antenna can work well using a combination of the bond wires with the bond wire inductivity compensation structure. In addition, as shown in FIGS. 5 and 6, the simulation results with the combination of the bond wire and bond wire inductivity compensation structure is close to the measurement and simulation results without bond wires. A simulation tool may be used to estimate the bond wire connection and compensation cases as analyzed above. Therefore, using the bond wire inductivity compensation structure in the designed package antenna can provide an extremely compact and elegant solution for communication systems operating at millimeter wave frequencies.

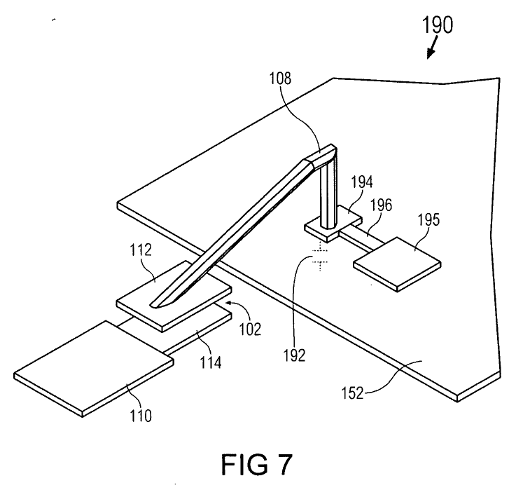

FIG. 7 shows a chip arrangement 190 including a capacitivity compensation structure 196 according to an embodiment of the present invention. For the typical bond wire contact structures, there is usually a ground under the signal pad 194. For example, a chip ground exists under a signal pad 194 of the die 152 or a chip. This ground and the signal pad 194 may form a capacitor 192 as shown in FIG. 7. One likely issue is that at mmWave frequencies, the signal may be shorted through this capacitor 192. The size of the mmWave signal pad 194 is usually minimized to decrease this shorting effect. However, there is a limit in fabrication for such minimization. Here, FIG. 7 shows a capacitivity compensation structure 196 which tries to solve this problem and consequently enhance the bond wire inductivity compensation structure 100 as shown earlier in FIG. 1. As shown in FIG. 7, a capacitivity compensation structure 196 or an inductor with a shorted end connected between the signal pad 194 and the ground pad 195 is used to tune the shorting capacitance 192 to a resonant condition, thus solving the signal shorting problem.

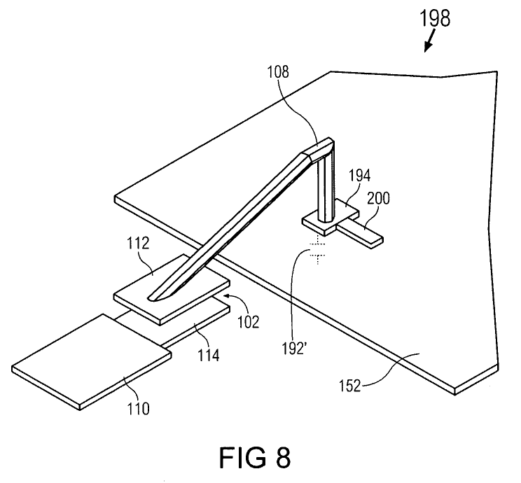

FIG. 8 shows a chip arrangement 198 including a capacitivity compensation structure 200 according to another embodiment of the present invention. For the same purpose, a capacitivity compensation structure 200 includes an inductor with an open end connected to the signal pad 194 as shown in FIG. 8. The inductor's dimensions may be appropriately calculated for compensation.

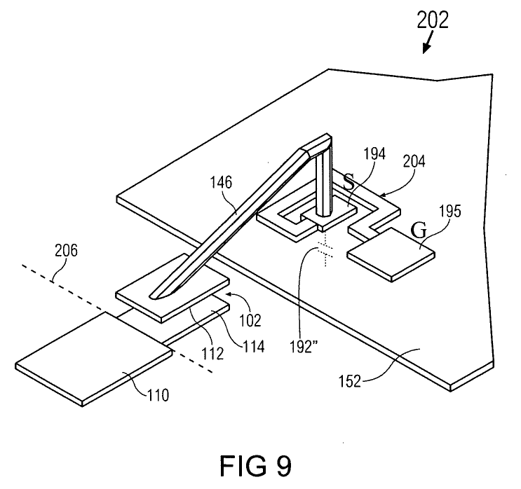

FIG. 9 shows a chip arrangement 202 including a capacitivity compensation structure 204 according to a further embodiment of the present invention. Due to the spacing limit of the signal pad 194 and ground pad 195 on a chip 152 as shown in FIG. 7, the capacitivity structure 204 having an inductor layout as shown in FIG. 9 provides a useful alternative. However, any suitable inductor layout may also be used. With the additional inductive compensation to the signal pad 194, the interconnect capabilities of the bond wire inductivity compensated structure 102 as shown earlier in FIG. 1 will be further enhanced at mmWave frequencies by only using conventional fabrication technologies. The signal pad 194 is connected to the bond wire inductivity compensation structure 102 via a bond wire 146. The second conductive plate 114 of the bond wire inductivity compensation structure 102 is connected to a feedline 110. The virtual reference plane 206 serves to distinguish the bond wire inductivity compensation structure 102 from the feedline 110.

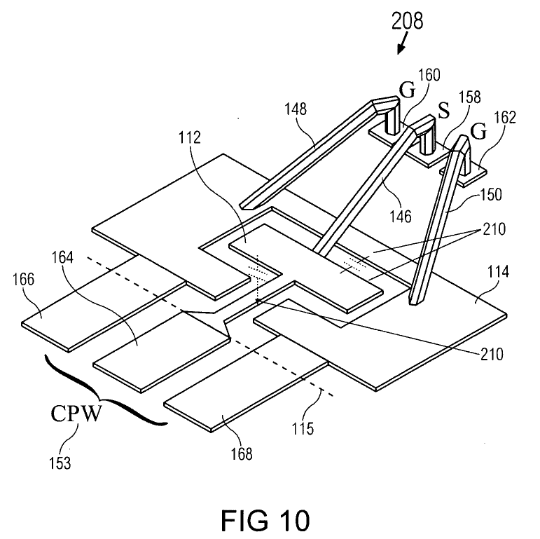

FIG. 10 shows a chip arrangement 208 including an inductivity compensation structure 210 according to another further embodiment of the present invention. The chip arrangement 208 includes a plurality of chip connectors 158, 160, 162 or chip pads, a plurality of respective bond wires 146, 148, 150, a first conductive plate 112, a second conductive plate 114 and a plurality of respective feedlines 164, 166, 168 of an antenna 153. The plurality of chip connectors or chip pads includes a first ground (G) pad 160, a signal (S) pad 158 and a second ground (G) pad 162. These respective chip pads 158, 160, 162 may be positioned adjacent to each other in the respective order of a first ground pad 160, a signal pad 158 and a second ground pad 162.

The signal pad 158 is connected to the first conductive plate 112 via the bond wire 146. The first ground pad 160 is connected to the second conductive plate 114 via the bond wire 148 and the second ground pad is also connected to the second conductive plate via the bond wire 150. The first conductive plate 112 has a T-shape and the second conductive plane 114 substantially surrounds the first conductive plate 112. The first conductive plate 112 and the second conductive plate 114 form the inductivity compensation structure 210. The first 112 and the second 114 conductive plates are configured such that a resonant condition for a partial circuit formed by the bond wire 146 and the inductivity compensation structure 210 is formed to compensate for the inductive element of the bond wire 146. Only the signal path of 146 is compensated. The other bond wires 148, 150 connect the grounds pads 160, 162 to the second conductive plate 114 accordingly to form the ground paths and environment for signal path compensation.

The antenna 153 adopts a coplanar waveguide T-network configuration and includes a plurality of feedlines, namely a first ground feedline 166, a signal feedline 164 and a second ground feedline 168. The first conductive plate 112 may be coupled to the signal feedline 158 and the second conductive plate 114 may be coupled to the first 166 and second 168 ground feedlines. A virtual plane 115 serves to distinguish the inductivity compensation structure 210 from the antenna 153.

In FIG. 10, the inductivity compensation structure 210 may be a shunt capacitor element used to tune the inductance of the bond wire 146 to a resonant condition, thus compensating the respective bond wire 146 high inductance at a resonant frequency. This chip arrangement 208 is convenient for bond wire compensation when the shunt capacitor is easily constructed with the available grounds. The inductivity compensation structure 210 enjoys the properties of manufacturing reliability and cost-effectiveness. It may be used for the commonly used chip-to-package connections at mmWave frequencies. This will be desirable for highly integrated mmWave wireless devices using bond wires.

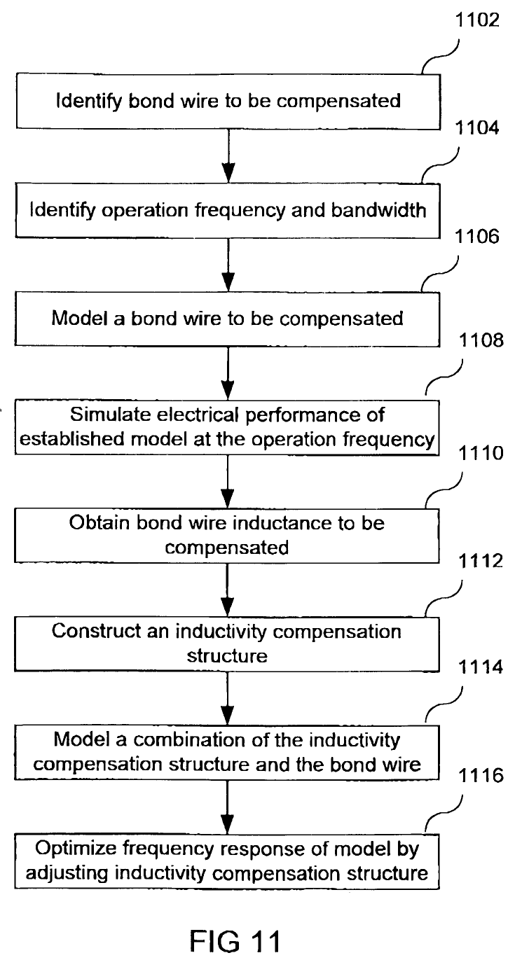

FIG. 11 shows a method of determining an inductivity compensation structure for compensating a bond wire inductivity in a chip arrangement according to an embodiment of the present invention. The method starts in 1102 where the bond wire to be compensated is identified. Then in 1104, the operation frequency and bandwidth is identified. In 1106, the bond wire to be compensated is modeled in the highly integrated device environment first. Then in 1108, the electrical performance of the established model is simulated at the operating frequency. In 1110, based on this simulation, the bond wire inductance to be compensated is obtained. Next in 1112, an inductivity compensation structure or a bond wire compensation structure is constructed in the highly integrated environment. Based on this structure, the capacitor dimensions are estimated to compensate the inductance value calculated in step 1110. In 1114, a model of the inductivity compensation structure in combination with the bond wire is obtained in the highly integrated device environment. Finally in 1116, the frequency response of the established model is optimized to the optimal by adjusting the inductivity compensation structure.

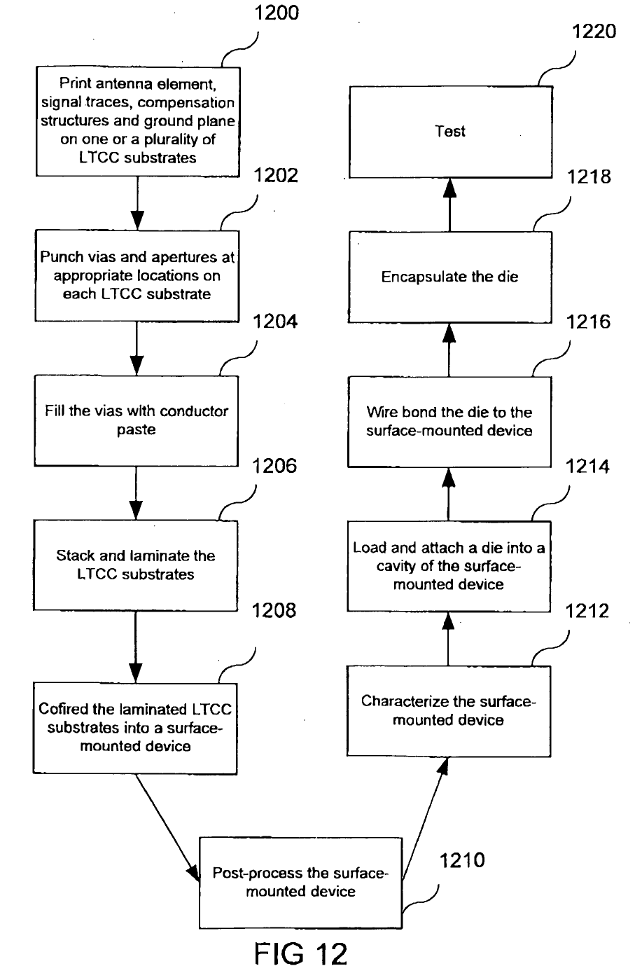

FIG. 12 shows a method of implementing an inductivity compensation structure for compensating a bond wire inductivity in a chip arrangement according to an embodiment of the present invention. The inductivity compensation structure can be implemented in printing fabrication technologies such as low temperature cofired ceramic (LTCC) and liquid crystal polymer (LCP) processes. An example of an implementation in LTCC process is illustrated. The method starts in 1200 where an antenna element, signal traces, compensation structures and ground plane are first printed on one or a plurality of LTCC substrate. Next in 1202, vias and apertures are punched at appropriate locations on each LTCC substrate. In 1204, the vias are filled with a conductor paste. In 1206, each of the plurality of LTCC substrates are stacked on top of each other and individually laminated. In 1208, the laminated pieces are cofired into the surface-mounted device (SMD). Then in 1210, the surface-mounted device is post-processed. In 1212, the surface-mounted device is characterized. After the LTCC fabrication of the surface-mounted device, the mmWave radio chip die is assembled into a cavity of the surface-mounted device. In 1214, the die is loaded and attached into the cavity in the surface-mounted device In 1216, the die is wire-bonded to the surface-mounted device. In 1218, the die is encapsulated and finally in 1220, the entire chip arrangement including the die and the inductivity compensation structure is tested.

The aforementioned description of the various embodiments has been presented for purposes of illustration and description. It is not intended to be exhaustive or to limit the invention to the precise form disclosed, and obviously many modifications and variations are possible in light of the disclosed teaching. It is intended that the scope of the invention be defined by the claims appended hereto.

What is claimed is:

1. A chip arrangement comprising:
a first chip;
a first bond wire having an inductive element and coupled with the first chip at its one end;
an inductivity compensation structure comprising a first conductive plate coupled with the first bond wire at the other end of the first bond wire, and a second conductive plate arranged in parallel to the first conductive plate;
wherein the first conductive plate and the second conductive plate are configured such that a resonant condition for a partial circuit formed by the first bond wire and the inductivity compensation structure is formed to compensate for the inductive element of the first bond wire.

2. The chip arrangement of claim 1,
wherein the second conductive plate forms part of an antenna.

3. The chip arrangement of claim 2,
wherein the first conductive plate and the second conductive plate are arranged on different chip arrangement manufacturing planes.

4. The chip arrangement of claim 3,
wherein the inductivity compensation structure is arranged in series with the first bond wire.

5. The chip arrangement of claim 2,
wherein the first conductive plate forms part of the antenna.

6. The chip arrangement of claim 5,
wherein the first conductive plate has a T-shape.

7. The chip arrangement of claim 6,
wherein the second conductive plate substantially surrounds the first conductive plate.

8. The chip arrangement of claim 7,
wherein the first conductive plate and the second conductive plate are arranged on a single chip arrangement manufacturing plane.

9. The chip arrangement of claim 8,
wherein the inductivity compensation structure is arranged in parallel with the first bond wire.

10. The chip arrangement of claim 1,
further comprising a second chip, wherein the second conductive plate forms part of the second chip,

11. The chip arrangement of claim 1,
wherein the first chip is an integrated circuit.

12. The chip arrangement of claim 10,
wherein the second chip is an integrated circuit.

13. The chip arrangement of claim 1,
wherein the first conductive plate comprises a metallic material.

14. The chip arrangement of claim 1,
wherein the second conductive plate comprises a metallic material.

15. The chip arrangement of claim 1,
wherein the first chip comprises a signal pad.

16. The chip arrangement of claim 15,
wherein the first bond wire is coupled with the signal pad on the first chip at its one end.

17. The chip arrangement of claim 16,
wherein the first chip further comprises a first ground pad.

18. The chip arrangement of claim 17,
wherein the signal pad is coupled to the first ground pad via a capacitivity compensation structure.

19. The chip arrangement of claim 18,
wherein the first chip comprises a second ground pad.

20. The chip arrangement of claim 19,
further comprises a second bond wire having an inductive element and coupled with the first chip at its one end.

21. The chip arrangement of claim 20,
wherein the second bond wire is coupled with the first ground pad on the first chip at its one end.

22. The chip arrangement of claim 21,
further comprises a third bond wire having an inductive element and coupled with the first chip at its one end.

23. The chip arrangement of claim 22,
wherein the third bond wire is coupled with the second ground pad on the first chip at its one end.

24. A method of determining an inductivity compensation structure for compensating a bond wire inductivity in a chip arrangement, the method comprising;
determining the inductivity of the bond wire; and
determining a first conductive plate coupled with the bond wire at its one end, and a second conductive plate arranged in parallel to the first conductive plate, which form the inductivity compensation structure such that a resonant condition for a partial circuit formed by the bond wire and the inductivity compensation structure is formed to compensate for the inductivity of the bond wire.

25. The method of claim 24,
wherein determining the inductivity of the bond wire comprises identifying the bond wire to be compensated.

26. The method of claim 25,
wherein determining the inductivity of the bond wire further comprises identifying an operation frequency and an operation bandwidth.

27. The method of claim 26,
wherein determining the inductivity of the bond wire further comprises modeling the bond wire to be compensated.

28. The method of claim 27,
wherein determining the inductivity of the bond wire further comprises simulating an electrical performance of the modeled bond wire at the operation frequency.

29. The method of claim 24,
wherein the second conductive plate forms part of an antenna.

30. The method of claim 29,
wherein the first conductive plate and the second conductive plate are arranged on different chip arrangement manufacturing planes.

31. The method of claim 30,
wherein the inductivity compensation structure is arranged in series with the bond wire.

32. The method of claim 29,
wherein the first conductive plate forms part of the antenna.

33. The method of claim 32,
wherein the first conductive plate has a T-shape.

34. The method of claim 33,
wherein the second conductive plate substantially surrounds the first conductive plate.

35. The method of claim 34,
wherein the first conductive plate and the second conductive plate are arranged on a single chip arrangement manufacturing plane.

36. The method of claim 35,
wherein the inductivity compensation structure is arranged in parallel with the bond wire.

37. The method of claim 24,
wherein the first conductive plate forms part of a first chip.

38. The method of claim 37,
wherein the second conductive plate forms part of a second chip.

39. The method of claim 37,
wherein the first chip is an integrated circuit.

40. The method of claim 38,
wherein the second chip is an integrated circuit.

41. The method of claim 24,
wherein the first conductive plate comprises a metallic material.

42. The method of claim 24,
wherein the second conductive plate comprises a metallic material.
